(19) United States
(12) Patent Application Publication
(10) Pub. No.: US 2025/0246397 A1
(43) Pub. Date: Jul. 31, 2025

(54) CHARGED-PARTICLE BEAM APPARATUS WITH LARGE FIELD-OF-VIEW AND METHODS THEREOF

(71) Applicant: ASML Netherlands B.V., Veldhoven (NL)

(72) Inventors: Xiaoyu JI, San Jose, CA (US); Weiming REN, San Jose, CA (US)

(73) Assignee: ASML Netherlands B.V., Veldhoven (NL)

(21) Appl. No.: 18/855,625

(22) PCT Filed: Mar. 16, 2023
(86) PCT No.: PCT/EP2023/056748

§ 371 Date: Oct. 9, 2024

Related U.S. Application Data
(60) Provisional application No. 63/331,644, filed on Apr. 15, 2022.

(51) Int. Cl. H01J 37/153; H01J 37/147; H01J 37/22; H01J 37/26; H01J 37/28

(52) U.S. Cl. CPC H01J 37/153; H01J 37/1475; H01J 37/1477; H01J 37/222; H01J 37/265; H01J 37/28; H01J 2237/1532; H01J 2237/1534; H01J 2237/24592

(57) ABSTRACT

Systems and methods of imaging a sample using a charged-particle beam apparatus are disclosed. The apparatus may include a charged-particle source configured to emit charged particles, an aperture plate configured to form a primary charged-particle beam along a primary optical axis from the emitted charged particles, a plurality of primary charged-particle beam deflectors configured to deflect the primary charged-particle beam to be incident on a surface of a sample to define a center of a field-of-view (FOV), and a controller including circuitry configured to apply a first excitation signal to a primary charged-particle beam deflector of the plurality of primary charged-particle beam deflectors to cause the primary charged-particle beam to scan a portion of the FOV of the sample, and apply a second excitation signal to cause the primary-charged particle beam deflector to compensate for an off-axis aberration of the primary charged-particle beam in the portion of the FOV.

### CROSS-REFERENCE TO RELATED APPLICATIONS

This application claims priority of U.S. application 63/331,644 which was filed on 15 Apr. 2022 and which is incorporated herein in its entirety by reference.

### TECHNICAL FIELD

The embodiments provided herein disclose a charged-particle beam apparatus, and more particularly an electron beam metrology and inspection apparatus with a large field-of-view (FOV) to detect defects and capture high-resolution images.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Although the imaging FOVs may be enlarged to increase the throughput, however, doing so may introduce off-axis aberrations of the primary electron beam, which negatively impact the imaging quality and overall image resolution.

### SUMMARY

One aspect of the present disclosure is directed to a charged-particle beam apparatus to image a sample. The apparatus may comprise a charged-particle source configured to emit charged particles, an aperture plate configured to form a primary charged-particle beam along a primary optical axis from the emitted charged particles, a plurality of primary charged-particle beam deflectors configured to deflect the primary charged-particle beam to be incident on a surface of a sample to define a center of a field-of-view (FOV), and a controller. The controller may include circuitry configured to apply a first excitation signal to a primary charged-particle beam deflector of the plurality of primary charged-particle beam deflectors to cause the primary charged-particle beam to scan a portion of the FOV of the sample, and apply a second excitation signal to cause the primary-charged particle beam deflector to compensate for an off-axis aberration of the primary charged-particle beam in the portion of the FOV of the sample.

Another aspect of the present disclosure is directed to a method for imaging a sample using a charged-particle beam apparatus. The method may include forming a primary charged-particle beam from charged particles emitted by a charged-particle source, deflecting, by a primary charged-particle beam deflector, the primary charged-particle beam to be incident on a surface of a sample to define a center of a field-of-view (FOV), applying a first excitation signal to the primary charged-particle beam deflector to cause the primary charged-particle beam to scan a portion of the FOV of the sample, and applying a second excitation signal to cause the primary-charged particle beam deflector to compensate for an off-axis aberration of the primary charged-particle beam in the portion of the FOV.

Yet another aspect of the present disclosure is directed to a charged-particle beam apparatus to image a sample. The apparatus may comprise a charged-particle source configured to emit charged particles, an aperture plate configured to form a primary charged-particle beam along a primary optical axis from the emitted charged particles, a plurality of primary charged-particle beam deflectors configured to deflect the primary charged-particle beam to be incident on a surface of a sample to define a center of a field-of-view (FOV), a plurality of beam separators, and a controller. The controller may include circuitry configured to apply a first excitation signal to a primary charged-particle beam deflector of the plurality of primary charged-particle beam deflectors to cause the primary charged-particle beam to scan a portion of the FOV of the sample, and apply a second excitation signal to a first beam separator of the plurality of beam separators to cause the first beam separator to compensate for an off-axis chromatic aberration of the primary charged-particle beam in the portion of the FOV.

Yet another aspect of the present disclosure is directed to a method for imaging a sample using a charged-particle beam apparatus. The method may include The method may include forming a primary charged-particle beam from charged particles emitted by a charged-particle source, deflecting, by a primary charged-particle beam deflector, the primary charged-particle beam to be incident on a surface of a sample to define a center of a field-of-view (FOV), applying a first excitation signal to the primary charged-particle beam deflector to cause the primary charged-particle beam to scan a portion of the FOV of the sample, and applying a second excitation signal to a first beam separator of a plurality of beam separators to cause the first beam separator to compensate for an off-axis chromatic aberration of the primary charged-particle beam in the portion of the FOV.

Yet another aspect of the present disclosure is directed to a charged-particle beam apparatus to image a sample. The apparatus may comprise a charged-particle source configured to emit charged particles, an aperture plate configured to form a primary charged-particle beam along a primary optical axis from the emitted charged particles, a plurality of primary charged-particle beam deflectors configured to deflect the primary charged-particle beam to be incident on a surface of a sample, and a controller. The controller may include circuitry configured to cause a cause a primary charged-particle beam deflector of the plurality of primary charged-particle beam deflectors to: perform a first beam alignment of the primary charged-particle beam at a first location in a field-of-view (FOV) of the sample, perform a second beam alignment of the primary charged-particle beam at a second location different from the first location, scan a first region of the sample with the primary charged-particle beam, the first region comprising a first portion of the FOV including the second location, perform a third beam alignment, after scanning the first region, of the primary charged-particle beam at a third location spaced at least a threshold distance away from the second location, and scan a second region of the sample with the primary charged-particle beam, the second region comprising a second portion of the FOV including the third location.

Yet another aspect of the present disclosure is directed to a method for imaging a sample using a charged-particle beam apparatus. The method may include forming a primary charged-particle beam from charged particles emitted by a charged-particle source of the charged-particle beam apparatus, performing a first beam alignment of the primary charged-particle beam at a first location in a field-of-view (FOV) of the sample, performing a second beam alignment of the primary charged-particle beam at a second location different from the first location, scanning a first region of the sample with the primary charged-particle beam, the first region comprising a first portion of the FOV including the second location, after scanning the first region, performing a third beam alignment of the primary charged-particle beam at a third location spaced at least a threshold distance away from the second location, and scanning a second region of the sample with the primary charged-particle beam, the second region comprising a second portion of the FOV including the third location.

Yet another aspect of the present disclosure is directed to a non-transitory computer readable medium storing a set of instructions that is executable by one or more processors of a charged-particle beam apparatus to cause the charged-particle beam apparatus to perform a method of imaging a sample. The method may include activating a charged-particle source to emit charged particles and forming a primary charged-particle beam from the emitted charged particles, deflecting the primary charged-particle beam to be incident on a surface of the sample to form define a center of a field-of-view (FOV), applying a first excitation signal to a primary charged-particle beam deflector to cause the primary charged-particle beam to scan a portion of the FOV of the sample, and applying a second excitation signal to cause the primary-charged particle beam deflector to compensate for an off-axis aberration of the primary charged-particle beam in the portion of the FOV.

Yet another aspect of the present disclosure is directed to a non-transitory computer readable medium storing a set of instructions that is executable by one or more processors of a charged-particle beam apparatus to cause the charged-particle beam apparatus to perform a method of imaging a sample. The method may include activating a charged-particle source to emit charged particles and forming a primary charged-particle beam from the emitted charged particles, deflecting the primary charged-particle beam to be incident on a surface of a sample to form define a center of a field-of-view (FOV), applying a first excitation signal to a primary charged-particle beam deflector to cause the primary charged-particle beam to scan a portion of the FOV of the sample, and applying a second excitation signal to a first beam separator of a plurality of beam separators to cause the first beam separator to compensate for an off-axis chromatic aberration of the primary charged-particle beam in the portion of the FOV.

Yet another aspect of the present disclosure is directed to a non-transitory computer readable medium storing a set of instructions that is executable by one or more processors of a charged-particle beam apparatus to cause the charged-particle beam apparatus to perform a method of imaging a sample. The method may include activating a charged-particle source to emit charged particles and forming a primary charged-particle beam from the emitted charged particles, performing a first beam alignment of the primary charged-particle beam at a first location in a field-of-view (FOV) of the sample, performing a second beam alignment of the primary charged-particle beam at a second location different from the first location, scanning a first region of the sample with the primary charged-particle beam, the first region comprising a first portion of the FOV including the second location, after scanning the first region, performing a third beam alignment of the primary charged-particle beam at a third location spaced at least a threshold distance away from the second location, and scanning a second region of the sample with the primary charged-particle beam, the second region comprising a second portion of the FOV including the third location.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram illustrating an exemplary electron beam tool for imaging a large field-of-view (FOV) of a sample, consistent with embodiments of the present disclosure.

FIGS. 4A and 4B are schematic diagrams illustrating an exemplary large FOV and a 3×3 array of sub-FOVs, respectively, consistent with embodiments of the present disclosure.

FIGS. 4C and 4D are schematic diagrams illustrating exemplary 3×3 arrays of sub-FOVs, consistent with embodiments of the present disclosure.

FIGS. 4E and 4F are schematic diagrams illustrating exemplary 5×5 arrays of sub-FOVs, consistent with embodiments of the present disclosure.

FIG. 5 is a process flowchart representing an exemplary method of imaging a large FOV of a sample, consistent with embodiments of the present disclosure.

FIG. 6 is a process flowchart representing an exemplary method of imaging a large FOV of a sample, consistent with embodiments of the present disclosure.

FIG. 7 is a process flowchart representing an exemplary method of imaging a large FOV of a sample, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Integrated circuits (ICs) are expected to perform more complex tasks with higher efficiency and faster processing speeds with each new process technology node, which necessitates complex device architectures to accommodate a higher density of active devices. A “technology node,” in the context of semiconductor device industry (e.g., “10 nm”), refers to the smallest size of a feature, such as a gate of a transistor or a half-pitch of a metal line, which can be reproducibly printed on a semiconductor wafer. Extreme Ultra-Violet (EUV) lithography systems, which use photons of a wavelength of 13.5 nm, may enable printing such nanoscopic features.

Although enabling, EUV lithography may present several challenges including generating local critical dimension (CD) variations due to stochastic effects, generating stochastic defects, or maintaining tight tolerances and process windows, among other things. In EUV lithography, the occurrence rate of stochastic defects is low and the dimensional variations to be detected are generally in the range of several nanometers, which makes detecting such defects very challenging. However, the size variations or the size of the defects that could render a device non-functional are also small, which means that it is important to detect these very challenging-to-detect defects. Though currently existing CD-SEM (Critical Dimension Scanning Electron Microscopy) imaging techniques can provide high resolution, they may be inadequate due to throughput limitations that limit the amount of area of a wafer that can be scanned with high resolution in a given time. One way to improve throughput is to increase the area of the wafer that is scanned between wafer movements, referred to as a field of view (FOV), as this would lead to fewer wafer movements during the scan of a given area, resulting in an increase in throughput. While increasing the FOV may improve throughput by reducing wafer movements, which take considerable time, doing so may cause a deterioration of imaging resolution due to, for example, an increase in off-axis aberrations of the primary electron beam associated with large FOV scanning. Off-axis aberrations of the incident primary electron beam may include astigmatism, off-axis chromatic aberrations, field curvature, or coma, among others. Therefore, it is desirable to provide systems and methods to enlarge the FOV while maintaining high resolution within the large FOV by, for example, minimizing one or more off-axis aberrations during scanning of the sample.

Some embodiments of the present disclosure are directed to systems and methods of imaging large FOVs of a sample. The method may include dividing a large FOV into sub-FOVs, which can be scanned by a primary electron beam of the CD-SEM apparatus. The off-axis aberrations, such as astigmatism, field curvature, off-axis chromatic aberration, of the primary electron beam, may be dynamically compensated while scanning by adjusting an excitation signal to one or more of primary electron beam deflectors. The method may further include applying an excitation signal to a beam separator to compensate for the energy dispersion of the primary electron beam caused by a Wien filter which is configured to deflect the secondary electrons toward an electron detector while allowing the primary electron beam to pass through undeflected to the sample. The method may additionally include scanning the sub-FOVs of a large FOV in a sequence such that the negative impact of charge build-up in successively scanned sub-FOVs is minimized or substantially mitigated.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

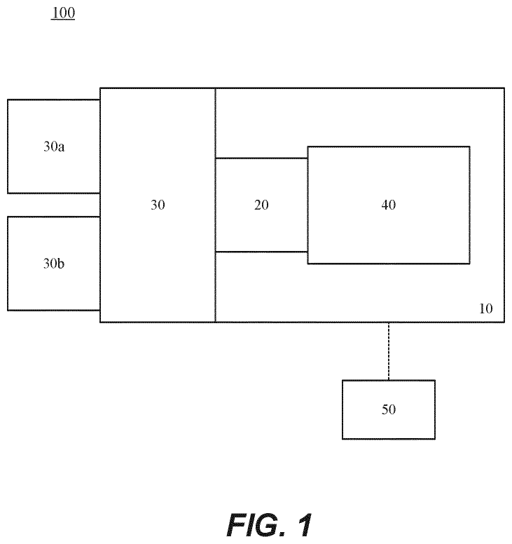

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

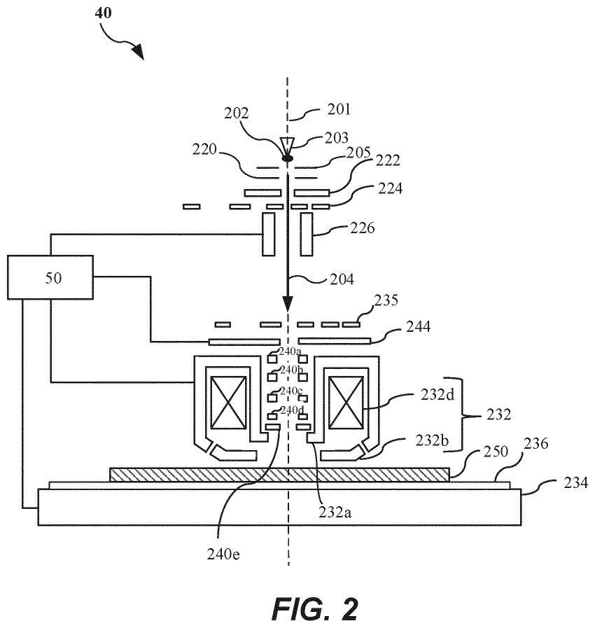

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

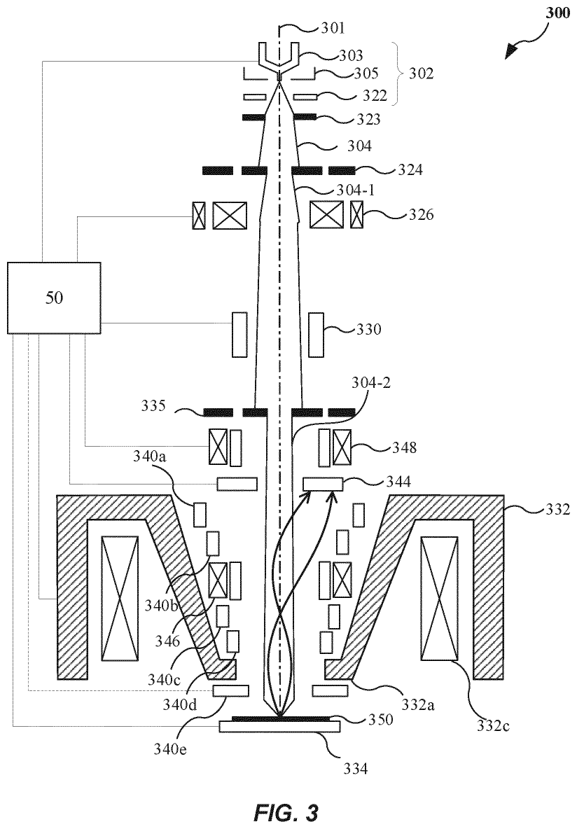

Reference is now made to FIG. 3, which is a schematic illustration of an exemplary electron beam tool 300, consistent with embodiments of the present disclosure. Electron beam tool 300 (also referred to herein as apparatus 300) may be used as a metrology, an inspection, or a review tool configured to detect the presence of physical defects such as micro-bridges between features, discontinuous lines, contact-hole mergers, missing contact holes, line edge roughness, among other defects.

Apparatus 300 may comprise an electron source 302 configured to generate electrons upon activation. In some embodiments, controller 50 may activate, deactivate, or control electron source 302 or elements thereof to regulate characteristics of electrons generated by electron source 302 by applying or adjusting one or more electrical signals to electron source 302. Characteristics of generated electrons may include number, intensity, acceleration, direction of emission, among other things. Electron source 302 may include a cathode 303, an extractor electrode 305, and an anode 322.

In some embodiments, apparatus 300 may further include an aperture plate 323 configured to block peripheral electrons exiting electron source 302 to form a primary electron beam 304 along a primary optical axis 301. Aperture plate 323 may comprise a plate with a single aperture of a predetermined size and arranged such that the geometric center of the aperture is aligned with primary optical axis 301. In some embodiments, aperture plate 323 may comprise one or more apertures, and the aperture used to form primary electron beam 304 may be aligned with primary optical axis 301.

As used in the context of this disclosure, “downstream” refers to a direction along the path of a primary electron beam (e.g., primary electron beam 304 of FIG. 3) starting from the electron source (e.g., electron source 302 of FIG. 3) towards the sample (e.g., sample 350 of FIG. 3). With reference to positioning of an element of a charged-particle beam apparatus (e.g., apparatus 300 of FIG. 3), “downstream” may refer to a position of an element located below or after another element, along the path of primary electron beam starting from the electron source, and “immediately downstream” refers to a position of a second element below or after a first element along the path of primary electron beam 304 such that there are no other active elements between the first and the second element. As used in the context of this disclosure, “upstream” may refer to a position of an element located above or before another element, along the path of primary electron beam starting from the electron source, and “immediately upstream” refers to a position of a second element above or before a first element along the path of primary electron beam 302 such that there are no other active elements between the first and the second element. As used herein, “active element” may refer to any element or component, the presence of which may modify the electromagnetic field between the first and the second element, either by generating an electric field, a magnetic field, or an electromagnetic field.

Apparatus 300 may include Coulomb aperture array 324 located downstream from aperture plate 323 to further block peripheral electrons of primary electron beam 304 and form primary electron beam 304-1. Coulomb aperture array 324 may be substantially similar to and may perform substantially similar functions as Coulomb aperture array 224 of FIG. 2. Coulomb aperture array 324 may comprise a plate including one or more apertures to allow a portion of primary electron beam 304 to pass through such that the coulombic interactions between electrons in primary electron beam 304-1 may be minimized while maintaining the desired beam characteristics. The apertures of Coulomb aperture array 324 may be uniform or non-uniform in shape, size, pitch, or cross-section, and may be arranged in a regular pattern to form an array or an irregular pattern. The geometric center of the aperture used to form primary electron beam 304-1 may be aligned with primary optical axis 301. In some embodiments, a position of Coulomb aperture array 324 may be adjustable along an axis substantially perpendicular or substantially parallel to primary optical axis 301. Adjusting the position of Coulomb aperture array 324 horizontally along a plane perpendicular to primary optical axis 301 may allow selection of a desired aperture. Adjusting the position of Coulomb aperture array 324 vertically along primary optical axis 301 may allow adjustment of the number of electrons allowed to pass through an aperture, thereby adjusting the beam size. In some embodiments, a position of Coulomb aperture array 324 may be adjusted horizontally, or vertically, or both, as appropriate.

Apparatus 300 may further include condenser lens 326 configured to condense primary electron beam 304-1 after exiting Coulomb aperture array 324. Condenser lens 326 may comprise an electrostatic, an electromagnetic, or a compound lens. In some embodiments, controller 50 may be configured to adjust excitation of condenser lens 326 by adjusting one or more electrical signals applied to condenser lens 326. Adjusting the excitation of condenser lens 326 may allow an adjustment of focusing power of condenser lens 326. In some embodiments, condenser lens 326 may be an adjustable condenser lens that may be configured so that the position of its first principal plane (not shown) is adjustable. In some embodiments, the adjustable condenser lens (e.g., condenser lens 326) may be electromagnetic. In alternative embodiments, condenser lens 326 may be an anti-rotation condenser lens, the focusing power of which may be changed without influencing a rotation angle of the electron beam (e.g., primary electron beam 304-1) passing therethrough. In some embodiments, condenser lens 326 may be an adjustable anti-rotation condenser lens, which may include an anti-rotation lens with an adjustable first principal plane. An adjustable anti-rotation lens may comprise two or more lenses, for example. Adjustable condenser lens and anti-rotation lens are further described in International Application No. PCT/EP2017/084429, which is incorporated herein by reference in its entirety.

Apparatus 300 may further include a stigmator 330 configured to partly or fully compensate for astigmatism aberration. In the context of this disclosure, astigmatism refers to an imaging artifact that distorts an image and occurs when the charged particles in the charged particle beam, typically electrons, are exposed to a non-uniform magnetic field as they traverse the path towards the sample surface. Some of the factors that may cause astigmatism include, but are not limited to, asymmetry of the pole pieces in electromagnetic lenses, impurities in the material from which lenses are made, contamination, charge accumulation, etc. One of the solutions to correct astigmatism is to use stigmators such as, for example stigmator 330, or micro-stigmators that introduce a compensating field to balance the inhomogeneities causing the astigmatism. The stigmators may comprise a magnetic or an electromagnetic multi-pole structure to create the compensating field. Commonly used multi-pole structures may include, but are not limited to, quadrupole, hexapole, octupole, and 12-pole stigmators. In some embodiments, controller 50 may adjust an electrical signal applied to stigmator 330 to adjust the compensating field such that the astigmatism aberration is minimized or compensated. Stigmator 330 may be located downstream from condenser lens 326.

Apparatus 300 may include a beam-limiting aperture array 335 configured to further block peripheral electrons of primary electron beam 304-1 and allow a portion of primary electron beam 304-1 to pass through, forming primary electron beam 304-2. Beam-limit aperture array 335 may include a plurality of beam limiting apertures. An aperture of beam-limit aperture array 335 may be configured to block peripheral electrons of primary electron beam 304-1 based on a desired probe size or the probe current of a probing beam incident on a sample surface. Beam-limit aperture array 335 may be electrically connected to controller 50 such that controller 50 may supply an electrical signal to adjust the aperture size, thereby adjusting the beam size or the beam current passing through the aperture of beam-limit aperture array 335. In some embodiments, beam-limit aperture array 335 may be located downstream from stigmator 330. Beam-limit aperture array 335 may be positioned such that the aperture through which primary electron beam 304-2 passes is aligned with primary optical axis 301. In some embodiments, an in-use aperture of aperture plate 323, in-use aperture of Coulomb aperture array 324, and an in-use aperture of beam-limit aperture array 335 may be aligned with each other and with primary optical axis 301. In this context, an in-use aperture is referred to the aperture through which the primary electron beam (e.g., primary electron beam 304 or 304-1) passes through.

Apparatus 300 may further include an objective lens 332 located downstream from beam-limit aperture array 335 and configured to focus primary electron beam 304-2 exiting beam-limit aperture array 335 onto a surface of sample 350. Objective lens 332, in some embodiments, may include a modified swing objective retarding immersion lens (SORIL), which includes a pole piece 332a, a control electrode 340e (also referred to herein as a beam scanning deflector), a beam manipulator assembly comprising primary electron beam deflectors 340a, 340b, 340c, 340d, and an exciting coil 332c. In a general imaging process, primary electron beam 304 emanating from the tip of cathode 303 is accelerated by an accelerating voltage applied to anode 322. A portion of primary electron beam 304 passes through aperture plate 323, and an aperture of Coulomb aperture array 324, and is focused by condenser lens 326 so as to fully or partially pass through an aperture of beam-limit aperture array 335. The electrons passing through the aperture of beam-limit aperture array 335 may be focused to form a probe spot on the surface of sample 350 by the modified SORIL lens and deflected by one or more deflectors of the beam manipulator assembly to scan the surface of sample 250. Secondary electrons emanated from the sample surface may be collected by electron detector 344 to form an image of the scanned area of interest.

In some embodiments, in objective lens 332, exciting coil 332c and pole piece 332a may generate a magnetic field. A part of sample 350 being scanned by primary electron beam 304-2 can be immersed in the magnetic field and can be electrically charged, which, in turn, creates an electric field. The electric field may reduce the energy of impinging primary electron beam 304-2 near and on the surface of sample 350. The control electrode, being electrically isolated from pole piece 332a, may control, for example, an electric field above and on sample 350 to reduce aberrations of objective lens 332 and control focusing situation of signal electron beams for high detection efficiency, or avoid arcing to protect sample from potential damage. One or more deflectors 340a-e of beam manipulator assembly may deflect primary electron beam 304-2 to facilitate beam scanning on sample 350. For example, in a scanning process, deflectors 340a, 340b, 340c, 340d, and 340e may be controlled to deflect primary electron beam 304 onto different locations of top surface of sample 350 at different time points, to provide data for image reconstruction for different parts of sample 350. It is to be appreciated that the order of arrangement of deflectors 340a-e may be different in different embodiments.

Apparatus 300 may further include a beam separator 346. In some embodiments, as illustrated in FIG. 3, beam separator 346 may be positioned closer to sample 350 and configured to allow primary electron beam 304-2 to pass through with zero deflection angles while deflecting secondary electrons (or secondary electron beams) toward electron detector 344. Beam separator 346 may be a Wien filter type beam separator comprising an electrostatic deflector generating an electrostatic dipole field and a magnetic dipole field (both of which are not shown in FIG. 3). If they are applied, the force exerted by the electrostatic dipole field on an electron of primary electron beam 304-2 may be equal in magnitude and opposite in direction to the force exerted on the electron by the magnetic dipole field, thus canceling each other. Primary electron beam 304-2 can therefore pass straight through beam separator 346 with zero deflection angle. However, the total energy dispersion of primary electron beam 304-2 generated by beam separator 346 may be non-zero.

In some embodiments, apparatus 300 may include one or more beam separators. As illustrated in FIG. 3, apparatus 300, in addition to beam separator 346, may include beam separator 348 located upstream from beam separator 346. In some embodiments, beam separator 348 may be of Wien filter type and configured to compensate the energy dispersion of primary electron beam 304-2 generated by beam separator 346. In some embodiments, beam separator 348 may be located upstream from electron detector 344 and upstream from objective lens 332. In some embodiments, beam separator 348 may be located downstream from beam-limit aperture array 335. In some embodiments, beam separator 348 may be located between beam-limit aperture array 335 and electron detector 344.

With each new generation, commonly referred to as a technology “node” in the semiconductor device industry, the number, density, performance, and complexity of transistors and electronic circuits increases. Higher density of transistors in an integrated circuit necessitates patterning smaller and three-dimensional features on a semiconductor substrate. Generally, the smaller the technology node means the smaller the feature size, producing smaller transistors which are both faster and more power-efficient. As a general guide, a technology or a process “node” may refer to a feature of a transistor including gate length, or metal line half-pitch, for example. One of the techniques in device fabrication to enable formation of such small features includes Extreme Ultra-Violet (EUV) lithography, which uses photons of wavelength of 13.5 nm and high numerical aperture (NA) to transfer patterns with high fidelity from a reticle or a mask to a wafer.

Although useful and enabling, high-NA EUV lithography technology may present challenges including generating local critical dimension (CD) variations due to stochastic effects, generating stochastic defects, or maintaining tight tolerances and process windows, among other things. In EUV lithography, the occurrence rate of stochastic defects is low and the dimensional variations to be detected are generally in the range of several nanometers. CD-SEM (Critical Dimension-SEM) imaging, due to its high resolution, may be a desirable imaging technique to detect the stochastic defects such as micro-bridges, broken lines, contact hole mergers, or protrusions, generated during the EUV Lithography process. However, the currently existing CD-SEM imaging technique may be inadequate or inefficient, due to its limitations in the area of a sample it can scan, referred to as the field-of-view (FOV). While increasing the FOV may seem like an obvious solution to overcome the limitations of CD-SEM imaging for stochastic defects, doing so may cause a deterioration of the imaging resolution at least due to an increase in off-axis aberrations of the primary electron beam associated with large FOV scanning. The off-axis aberrations of the incident primary electron beam may include astigmatism, off-axis chromatic aberrations, field curvature, or coma. Therefore, it may be desirable to provide systems and methods to increase the FOV while maintaining high resolution within the large FOV and to minimize one or more off-axis aberrations during scanning of the sample. Additionally, a large FOV may help improve the imaging throughput by reducing the time spent in wafer stage movement and settling every time a new location is scanned.

In currently existing SEM-based wafer metrology techniques such as CD-SEM imaging, a focused primary electron beam (e.g., primary electron beam 304-2 of FIG. 3) may be scanned over a region of interest of a sample (e.g., sample 350 of FIG. 3). The region of interest may comprise an underlying sub-surface structure, a defect, a node, a topographical feature, or the like. The scanned region of interest may form the field-of-view (FOV) of the sample. As mentioned earlier, although CD-SEM imaging allows for high resolution imaging, the FOVs are small, usually 10 μm or less. To detect the stochastic defects introduced by the EUV Lithography, which are fewer and smaller in size, it may be desirable to increase the FOV and maintain the resolution within the FOV to render CD-SEM imaging efficiently.

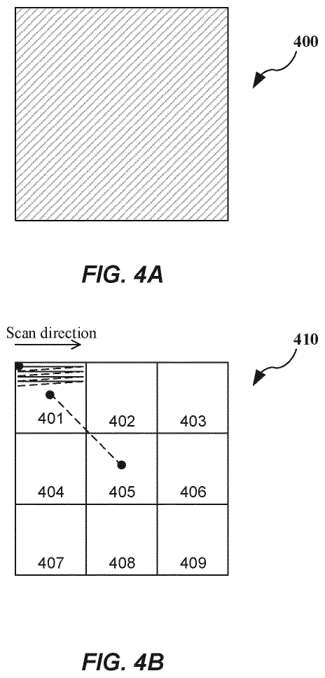

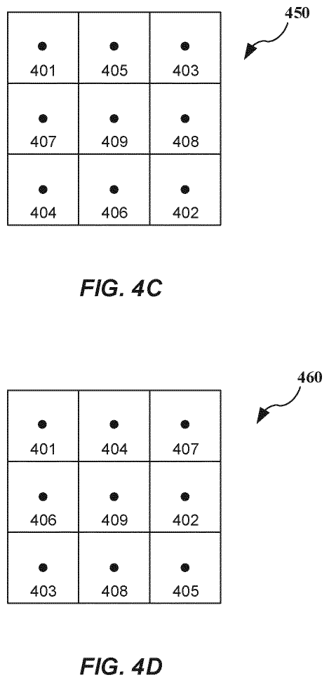

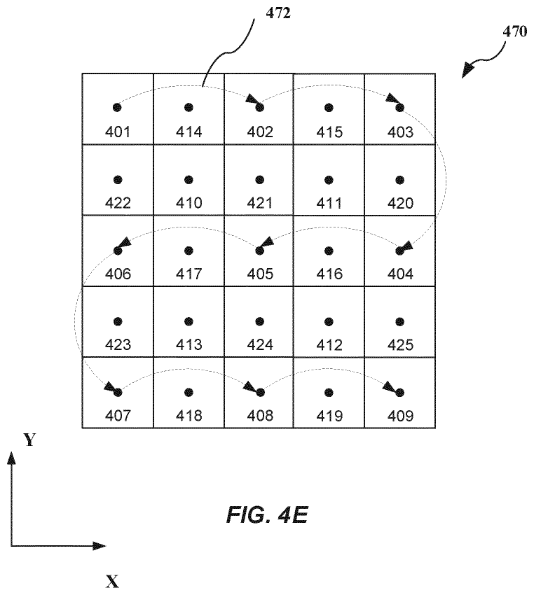

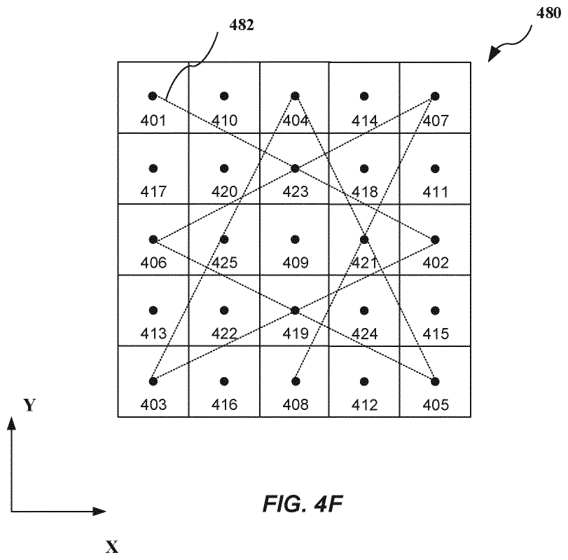

Reference is now made to FIGS. 4A and 4B, which illustrate schematic diagrams of an exemplary large FOV and an array of sub-FOVs constituting a large FOV, respectively, consistent with embodiments of the present disclosure. It is to be appreciated that although the size of a FOV is expressed in linear units such as micrometers (μm), the field-of-view refers to an “area,” generally a square region of interest on the sample surface. As an example, a FOV of 10 μm refers to a square region of the sample, one side of which is approximately 10 μm, and the area of the FOV may thus be approximately 100 μm².

FIG. 4A illustrates an exemplary large FOV 400, which may be larger in size than the conventional FOVs in a CD-SEM. For example, the size of large FOV 400 may be 10 μm or more, 20 μm or more, 30 μm or more, 40 μm or more, 50 μm or more, 60 μm or more, 70 μm or more, 80 μm or more, 100 μm or more, or any size appropriate for detecting defects while maintaining the inspection throughput and resolution. In some embodiments, large FOV 400 may be at least 2× larger than conventional FOV, at least 5× larger than conventional FOV, at least 10× larger than conventional FOV, at least 20× larger than conventional FOV, at least 40× larger than conventional FOV, at least 50× larger than conventional FOV, at least 80× larger than conventional FOV, or at least 100× larger than conventional FOV.

FIG. 4B illustrates an exemplary large FOV 410, which comprises a plurality of sub-FOVs 401-409. A sub-FOV, as used herein, refers to a portion of a large FOV which may be scanned by primary electron beam 304-2. It is to be appreciated that although exemplary large FOV 410 of FIG. 4B illustrates a 3×3 array of sub-FOVs, other arrayed configurations are possible as well. For example, large FOV 410 may include, but is not limited to, a 2×2 array, or a 4×4 array, or a 5×5 array (shown in FIGS. 4C-4E), or an m×n array, where m and n are integers, and m=n, or m≠n.

Enabling large FOV 410 imaging using apparatus 300 may include scanning sub-FOVs 401-409. In some embodiments, beam deflectors (e.g., beam deflectors 340a-e of FIG. 3) of beam manipulation assembly may be configured to deflect primary electron beam 304-2 such that it scans a region of a sample to form a large FOV. In some embodiments, configuring beam deflectors 340a-e may include applying, or adjusting one or more signals to adjust the deflection, scan frequency, among other things. One of several challenges in enabling large FOV imaging using CD-SEM includes maintaining the resolution while increasing the FOV size. A skilled artisan in the field of semiconductor device inspection and metrology would appreciate that as the FOV of a CD-SEM inspection tool is increased, the imaging resolution deteriorates due to increasing off-axis aberrations such as astigmatism, chromatic aberrations, field curvature, and coma, among other things.

Some of several techniques to minimize the impact of off-axis aberrations in loss of resolution may include, but are not limited to, optimizing one or more beam deflectors 340a-e to adjust scan characteristics, or dividing large FOV (e.g., large FOV 410 of FIG. 4B) into a plurality of sub-FOVs (e.g., sub-FOVs 401-409 of FIG. 4B), or both. In some embodiments, achieving a large FOV may include two beam movements—moving primary electron beam 304-2 from one sub-FOV to another sub-FOV (slow-scan) and scanning primary electron beam 304-2 within each sub-FOV (fast-scan or quick-scan).

In some embodiments, beam deflectors 340a, 340d, and 340e may be configured to cause primary electron beam 304-2 to slow-scan to move the probe spot (indicated as the dark solid circle in the center of sub-FOV 405 of FIG. 4B) formed by primary electron beam 304-2 from center of sub-FOV 405 to center of sub-FOV 401. As illustrated, center of sub-FOV 405 may coincide with center of large FOV 410. The dotted line connecting the centers of sub-FOVs 405 and 401 represents an exemplary path of deflection of primary electron beam 304-2. Beam deflectors 340a, 340d, and 340e may be electrostatic deflectors configured to deflect primary electron beam 304-2 from center of large FOV 410 (which coincides with center of sub-FOV 405) to be incident on a region of the sample represented by sub-FOV 401. Controller 50 may apply or adjust an applied signal to beam deflectors 340a, 340d, and 340e to cause deflection of primary electron beam 304-2 from center of sub-FOV 405 to center of sub-FOV 401. Enabling the slow scan step may further include aligning primary electron beam 304-2 at the center of sub-FOV 401 prior to fast scanning primary electron beam 304-2 within sub-FOV 401. Beam deflectors 340b and 340c may be configured to cause primary electron beam 304-2 to fast-scan sub-FOV 401 after primary electron beam 304-2 is aligned at the center of sub-FOV 401. In some embodiments, fast-scanning sub-FOV 401 may include adjusting signals to beam deflectors 340b and 340c such that primary electron beam 304-2 scans from a left edge of sub-FOV 401 to a right edge of sub-FOV 401 (represented by solid horizontal lines), as indicated in FIG. 4B. Within sub-FOV 401, upon reaching the right edge of the first row, primary electron beam 304-2 may be deflected and positioned to the left edge of the second row (represented by dashed lines) vertically below the first row. The row-to-row scanning pattern may be repeated to scan sub-FOV 401. After scanning sub-FOV 401, controller 50 may apply a signal to beam deflectors 340a, 340d, and 340e to enable deflection of primary electron beam 304-2 to the center of the neighboring sub-FOV 402, which is scanned using the fast-scanning regime similar to sub-FOV 401. It is to be appreciated that the numbering of sub-FOVs 401-409 does not necessarily, although it may, indicate the order in which the sub-FOVs are scanned. As an example, sub-FOV 406 may be scanned immediately after sub-FOV 401 is scanned so as to increase the physical distance between two successive scans of sub-FOVs to allow any charge build-up to dissipate, among other reasons. In some instances, an overlap in the scanned regions of adjacent sub-FOVs may negatively affect the image resolution due to charging, or may even generate defects, among other issues.

Although useful in minimizing the impact of off-axis aberrations, in some cases, the off-axis aberrations may still be undesirably large for a large FOV. Dividing a large FOV into sub-FOVs, which may be individually scanned, may not provide adequate resolution to detect the stochastic defects associated with the EUV lithography technique. This may be because the primary electron beam (e.g., primary electron beam 304-2 of FIG. 3) configured to scan the region of the sample within a sub-FOV (e.g., sub-FOV 401 of FIG. 4B) may have off-axis aberrations, which may negatively affect the resolution of the generated images. Therefore, it may be desirable to provide methods and systems to compensate the off-axis aberrations of primary electron beam 304-2 during scanning of the sub-FOVs.

Referring back to FIG. 3, apparatus 300 may be configured to compensate one or more off-axis aberrations of primary electron beam 304-2 during scanning a region of sample 350. The off-axis aberrations may include coma, astigmatism aberrations, off-axis chromatic aberrations, or field curvature. In some embodiments, an aberration compensation mechanism may be used to reduce one or more off-axis aberrations in each sub-FOV of a large FOV. The aberration compensation mechanism may be configured to dynamically compensate one or more off-axis aberrations within each sub-FOV of a large FOV, thereby enabling imaging a large FOV with dynamic compensation of off-axis aberrations to allow detection of defects such as, but not limited to, stochastic defects generated by EUV lithography techniques.

In some embodiments, a deflector of beam manipulator assembly may be configured to compensate the astigmatism aberration within a sub-FOV. In some embodiments, any one of deflectors 340a-e may be configured to compensate the astigmatism aberration. Controller 50 may apply an electrical excitation signal to any one of deflectors 340a-e to deflect primary electron beam 304-2 such that the astigmatism aberration is compensated. The electrical excitation signal may comprise a voltage signal, for example. In some embodiments, the excitation signal applied to a deflector to compensate the astigmatism aberration may be a supplemental excitation signal such as a voltage signal, in addition to the primary excitation signal applied to the deflector. The supplemental excitation signal may be substantially smaller than the primary excitation signal applied to the deflector. In this context, substantially smaller refers to 10% or less of the primary excitation signal. For example, if the primary excitation signal is 100 V, the supplemental excitation signal may be 10 V or less.

In some embodiments, supplemental excitation signal to compensate astigmatism aberration may be a predetermined signal based on the astigmatism aberration of primary electron beam 304-2. In some embodiments, the astigmatism aberration may be determined based on simulations or trained models such as through artificial learning, or machine learning models. The information associated with simulated astigmatism aberration values may be stored in a database or a storage module in a network such that the stored information may be accessed and utilized by a processor or controller 50 to adjust the applied electrical signal to the corresponding deflector.

In some embodiments, the predetermined supplemental excitation signal to compensate the astigmatism aberration within a sub-FOV may be a constant signal such that the excitation signal is uniform across the sub-FOV. For example, if the predetermined supplemental excitation signal for sub-FOV 401 is 10 V, and the primary excitation signal is 100 V, the excitation signal for sub-FOV 401 may be 110 V at each probing location within sub-FOV 401. In some embodiments, the predetermined supplemental excitation signal for one or more sub-FOVs may be substantially similar or dissimilar based on a location of sub-FOV with respect to primary optical axis, location of the probe spot, or distribution of electrons in primary electron beam 304-2, among other things.

In some embodiments, the predetermined supplemental excitation signal to compensate the astigmatism aberration may vary within a sub-FOV such that the excitation signal at pixels within a sub-FOV may be non-uniform. In the context of this disclosure, a probing location within a sub-FOV may be referred to as a pixel of the sub-FOV. Controller 50 may be configured to adjust the excitation signal applied to the deflector associated with compensating the astigmatism aberration. In some embodiments, controller 50 may be configured to adjust the excitation signal at every pixel by applying a predetermined supplemental excitation signal, which may be similar or dissimilar.

In some embodiments, astigmatism aberration may be compensated by applying an excitation signal to stigmator 330, or by applying an excitation signal including a supplemental excitation signal to any one of deflectors 340a-e, or by applying an excitation signal to stigmator 330 and one of deflectors 340a-e.

Referring back to FIG. 3, a deflector of apparatus 300 may be configured to compensate the field curvature aberration within a sub-FOV. In some embodiments, any one of deflectors 340a-e may be configured to compensate the field curvature aberration. Controller 50 may apply an electrical excitation signal to any one of deflectors 340a-e to deflect primary electron beam 304-2 such that the field curvature aberration is compensated. The electrical excitation signal may comprise a voltage signal, for example. In some embodiments, the excitation signal applied to a deflector to compensate the field curvature, may be a supplemental excitation signal such as a voltage signal, in addition to the primary excitation signal applied to the deflector. The supplemental excitation signal may be substantially smaller than the primary excitation signal applied to the deflector.

In some embodiments, the predetermined supplemental excitation signal to compensate the field curvature aberration within a sub-FOV may be a constant signal such that the excitation signal is uniform across the sub-FOV. For example, if the predetermined supplemental excitation signal for sub-FOV 401 is 10 V, and the primary excitation signal is 100 V, the excitation signal for sub-FOV 401 may be 110 V at each probing location within sub-FOV 401. In some embodiments, the predetermined supplemental excitation signal for one or more sub-FOVs may be substantially similar or dissimilar based on a location of sub-FOV with respect to primary optical axis, location of the probe spot, or distribution of electrons in primary electron beam 304-2, among other things.

In some embodiments, the predetermined supplemental excitation signal to compensate the field curvature aberration may vary within a sub-FOV such that the excitation signal at pixels within a sub-FOV may be non-uniform. Controller 50 may be configured to adjust the excitation signal applied to the deflector associated with compensating the field curvature aberration. In some embodiments, controller 50 may be configured to adjust the excitation signal at every pixel by applying a predetermined supplemental excitation signal, which may be similar or dissimilar.

In some embodiments, apparatus 300 may be configured to compensate the field curvature aberration by adjusting an excitation signal to objective lens 332, or adjusting an excitation signal to beam deflector 340e, or adjusting an excitation signal to condenser lens 326, or adjusting a lens field excitation signal to one of beam deflectors 340a-d, or a combination thereof. In the context of this disclosure, adjusting an excitation signal may include, but is not limited to, adding a supplemental excitation signal to a primary excitation signal, or varying the primary excitation signal to effect aberration compensation.

Referring to FIG. 3, beam separator 348 may be configured to compensate the off-axis chromatic aberration for each sub-FOV. In some embodiments, beam separator 348 may be configured to compensate the off-axis chromatic aberration and energy dispersion of primary electron beam 304-2 caused by beam separator 346. As illustrated in FIG. 3, beam separator 348 may be located upstream from beam separator 346 and downstream from beam-limit aperture array 335. The electrostatic and the magnetic force applied by beam separator 346 on the incoming primary electron beam 304-2 may be balanced such that a portion of primary electron beam 304-2 may pass through beam separator 346 undeflected. However, because primary electron beam 304-2 comprises electrons having an energy distribution, for example 1 eV or less, some electrons may experience energy dispersion as they pass through. In some embodiments, beam separator 348 may be configured to compensate for the energy dispersion of primary electron beam 304-2 caused by beam separator 346. In some embodiments, the energy dispersion of primary electron beam 304-2 may be determined based on characteristics of primary electron beam 304-2 and the excitation signal to beam separator 348 may be based on the determined energy dispersion of primary electron beam 304-2. The excitation signal may include a component to compensate the off-axis chromatic aberration of primary electron beam 304-2 as well.

In some embodiments, two or more deflectors of apparatus 300 may be configured to reduce coma aberrations. In some embodiments, excitation signals may be applied to at least deflectors 340a and 340e to reduce coma aberrations of primary electron beam 304-2, or excitation signals applied may be applied to at least deflectors 340d and 340e to reduce coma aberrations of primary electron beam 304-2. In some embodiments, excitation signals applied to deflectors 340a, 340d, and 340e may reduce coma aberrations of primary electron beam 304-2.

As discussed above, one of several ways to maintain high imaging resolution in large FOV includes dividing the large FOV into sub-FOVs and dynamically compensating one or more off-axis aberration during scanning the sub-FOVs. Additionally, or alternatively, in some instances, the sequence of scanning the sub-FOVs may be adjusted as well to minimize the negative effects of “charging” or “charge build-up,” thereby improving overall image quality. It is appreciated that irradiating a sample surface with charged particles such as electrons, may cause an accumulation of the charged particles within the surface in absence of a charge dissipation mechanism. The accumulated charged particles may negatively impact the overall imaging quality, and in some cases, may also hinder detection of defects, rendering the defect inspection apparatus inadequate. Therefore, it may be desirable to provide a method to minimize the impact of charging when scanning large FOVs for defect detection or imaging.

Reference is now made to FIGS. 4C and 4D, which illustrate exemplary 3×3 arrays of sub-FOVs 401-409, consistent with embodiments of the present disclosure. In some embodiments, the large FOVs may be divided into a symmetric array of sub-FOVs such as a 3×3 array, or a 5×5 array, or a 7×7 array. In some embodiments, the large FOVs may be divided into an asymmetric array of sub-FOVs such as a 2×4 array, or a 3×5 array, etc. Although FIGS. 4C and 4D illustrate a symmetric 3×3 array, it is to be appreciated that a large FOV may be divided into other arrayed arrangements as well, represented by a m×n array where m and n are integers and m=n or m≠n. It is to be appreciated that the boundaries defining the squares shown in FIGS. 4A-4D are merely illustrative, exemplary, and for visual aid only. In practice, however, the primary electron beam (e.g., primary electron beam 304-2) may be deflected by a range of distances from a reference point to scan the area bound within or represented by the sub-FOVs.

FIG. 4C illustrates a large FOV 450 comprising a plurality of sub-FOVs 401-409. In the embodiment shown in FIG. 4C, the numbering of sub-FOVs indicates the sequence or the order of scanning of sub-FOVs 401-409 within large FOV 450. In some embodiments, scanning large FOV 450 with primary electron beam 304-2 may include the steps of, but is not limited to, aligning primary electron beam 304-2 with a center of large FOV 450; adjusting the position of primary electron beam 304-2 from center of large FOV 450 to center of sub-FOV 401; aligning primary electron beam 304-2 with a center of sub-FOV 401; scanning primary electron beam 304-2 across sub-FOV 401; after scanning sub-FOV 401, adjusting the position of primary electron beam 304-2 to align with a center of sub-FOV 402, and scanning primary electron beam 304-2 across sub-FOV 402. It is appreciated that scanning large FOV 450 may include more or fewer steps, as appropriate.

To mitigate the effect of charging in a large FOV (e.g., large FOV 450), the sequence of scanning of sub-FOVs may be adjusted to maximize the physical separation between successively scanned sub-FOVs. The physical separation and the time elapsed between successive scans may allow the built-up charges to dissipate. Therefore, increasing the spatial and physical separation between two successively scanned sub-FOVs may increase the time between two scans, and thus mitigate the issues related with charge-build up.

In some embodiments, successively scanned sub-FOVs such as, sub-FOV 401, sub-FOV 402, may be physically or spatially separated by at least a threshold distance. The threshold distance of separation may depend on factors including, but not limited to, probing beam intensity, sample material, presence of defects, type of defects present, among other things, while considering the overall imaging quality and inspection throughput. In some embodiments, a large FOV may be divided into substantially equally sized sub-FOVs. In such cases, the threshold distance may be expressed in terms of unit sub-FOVs. For example, the threshold distance between two successively scanned sub-FOVs may be one sub-FOV, or two sub-FOVs, or three sub-FOVs, or any distance therebetween, or any appropriate distance. It is to be appreciated that the distance between two sub-FOVs, in this context, refers to the horizontal distance along the surface of the sample, between the geometric centers of two sub-FOVs.

As illustrated in FIG. 4C, sub-FOV 402, which may be scanned after scanning sub-FOV 401, is located diagonally opposite to sub-FOV 401, the maximum distance in a square array arrangement. It is to be appreciated that although not always possible, the distance between two successively scanned sub-FOVs may be maximized. For example, the physical distance between sub-FOV 402 and sub-FOV 403 may be smaller than the physical distance between sub-FOV 410 and sub-FOV 402, however, the distance between sub-FOV 402 and sub-FOV 403 is the maximum possible distance within large FOV 450. As indicated above, the numbering of sub-FOVs in large FOV 450 represents the order of scanning.

In some embodiments, as illustrated in FIG. 4D, the physical distance between successively scanned sub-FOVs such as, sub-FOV 401, sub-FOV 402, sub-FOV 403, sub-FOV 404, may be uniform or substantially uniform. In this context, substantially uniform separation distance refers to a negligible variation in the separation distance between two successively scanned sub-FOVs across a large FOV. It is appreciated that physical separation distance between successively scanned sub-FOVs such as, sub-FOV 401, sub-FOV 402, may not be the maximum physical separation possible. It is also appreciated that the physical separation between sub-FOV 408 and sub-FOV 409 may be different, more specifically, less compared to the physical separation between sub-FOV 407 and sub-FOV 408, for example. FIG. 4D illustrates a large FOV 460 divided into a plurality of sub-FOVs 401-409 arranged in an array pattern such that the physical separation between successively scanned sub-FOVs is the maximum physical separation while being separated by a uniform distance.

Reference is now made to FIGS. 4E and 4F, which illustrate exemplary scanning patterns of sub-FOVs within a large FOV, consistent with embodiments of the present disclosure. FIGS. 4E and 4F illustrate exemplary scanning patterns within a large FOV 470 and a large FOV 480, respectively. Large FOV 470 and 480 comprise a 5×5 symmetric array of sub-FOVs 401-425. The scanning patterns 472 and 482 are represented by the broken lines connecting the centers of sub-FOVs to be scanned successively. Scanning pattern 472 may comprise a “skip” pattern where after scanning a sub-FOV such as, sub-FOV 401, the primary electron beam 304-2 is deflected to scan a region of the sample separated by at least one sub-FOV along the X-axis, or Y-axis, or a combination of the X- and the Y-axes. In large FOV 470, scanning pattern 472 may comprise a combination of a skip pattern and other regular or irregular patterns, such that a maximum possible physical separation is maintained between two successively scanned sub-FOVs while maintaining a substantially uniform separation distance, based on the scanning area.

In some embodiments, scanning pattern 482 of large FOV 480 may comprise a “star” pattern. It is to be appreciated that although the broken lines represent the pattern and the shortest path to the desired sub-FOV for scanning, other paths may be implemented as well. In some embodiments, a scanning pattern may include a combination of a star pattern, a skip pattern, or any regular or irregular patterns, or any combinations thereof.

In some embodiments, scanning patterns 472 or 482 may be predetermined patterns based on factors including, but not limited to, total scan area, information associated with type of defects, information associated with number of defects, desired imaging resolution, among other things. In some embodiments, predetermined patterns may be based on simulated patterns generated by a trained model such as a machine learning model or an artificial intelligence-based model.

In some embodiments, controller 50 of apparatus 300 may be configured to cause deflection of primary electron beam 304-2 such that primary electron beam 304-2 follows a path based on the predetermined scanning pattern. One or more beam deflectors 340a-e, controlled by controller 50, may be configured to deflect primary electron beam 304-2 by applying an excitation signal. The applied excitation signal may be a voltage signal for electrostatic beam deflectors such as deflector 340a, for example.

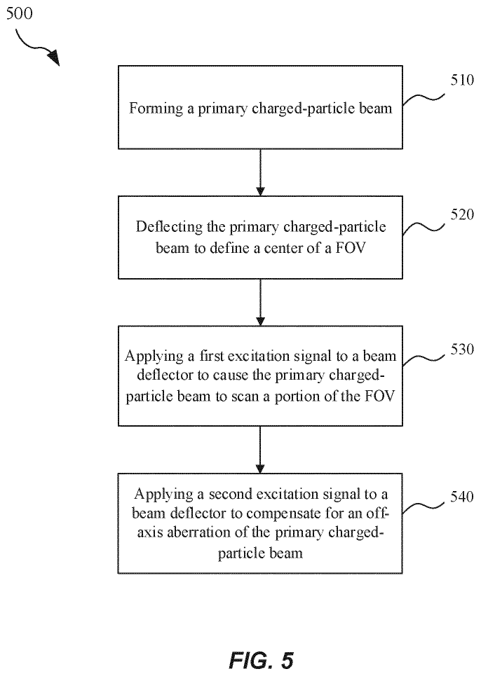

Reference is now made to FIG. 5, which illustrates a process flowchart representing an exemplary method 500 of imaging a large FOV of a sample, consistent with embodiments of the present disclosure. One or more steps of method 500 may be performed by controller 50 of EBI system 100, as shown in FIG. 2, for example. For example, controller 50 may instruct a module of a charged particle beam apparatus to activate a charged-particle source to generate charged particle beam (e.g., electron beam), apply electrical signals to beam deflectors, apply electrical signals to beam separators, and carry out other functions.

In step 510, a charged-particle source (e.g., electron source 302 of FIG. 3) may be activated to emit charged particles. The charged particles may pass through an aperture to form a charged-particle beam (e.g., primary charged-particle beam 304 of FIG. 3). The electron source may be activated by a controller (e.g., controller 50 of FIG. 3). For example, the electron source may be controlled to emit primary electrons to form an electron beam along a primary optical axis (e.g., primary optical axis 301 of FIG. 3). The electron source may be activated remotely, for example, by using a software, an application, or a set of instructions for a processor of a controller to power the electron source through a control circuitry. The primary electron beam may pass through a Coulomb aperture array (e.g., Coulomb aperture array 324 of FIG. 3) and a beam-limit aperture array (e.g., beam-limit aperture array 335 of FIG. 3) to adjust the beam size or beam current of the primary electron beam and form a probing beam (e.g., primary charged-particle beam 304-2 of FIG. 3).

In step 520, the probing beam may be deflected from the primary optical axis such that scanning the deflected probing beam on a surface of a sample (e.g., sample 350 of FIG. 3) forms a field-of-view (FOV). The controller may be configured to apply an excitation signal to one or more beam deflectors (e.g., primary charged-particle beam deflectors 340a-e of FIG. 3) in a beam manipulator assembly of the inspection apparatus (e.g., apparatus 300 of FIG. 3) to deflect the probing beam. The applied excitation signal may scan the deflected probing beam across a region of interest (ROI) to form the FOV of the image.

To detect defects such as stochastic defects, generated by EUV lithography, it may be desirable to form large FOVs with a dynamic aberration compensation mechanism. One of several challenges associated with increasing the FOV in Critical-Dimension Scanning Electron Microscopy (CD-SEM) includes deterioration in imaging resolution as the size of the FOV increases. This loss of imaging resolution may be attributed to off-axis aberrations of the probing beam such as a primary electron beam. The off-axis aberrations may include astigmatism aberration, field curvature aberration, chromatic aberration, or coma. Therefore, it may be desirable to provide methods of compensating one or more of the off-axis aberrations of the probing beam to maintain the imaging resolution as the size of the imaging FOV is increased to detect nanoscopic defects. A large FOV may be imaged by scanning a plurality of portions of the large FOV and dynamically compensating off-axis aberrations in each portion. A portion of the large FOV (e.g., large FOV 410 of FIG. 4B) is referred to herein as a sub-FOV (e.g., sub-FOV 401-409 of FIG. 4B).

In step 530, the controller may apply an excitation signal to one or more beam deflectors to cause the probing beam to deflect and scan a sub-FOV. The controller may apply an excitation signal to one or more deflectors such as primary beam deflectors 340a, 340d, and 340e to adjust the position of the probing beam from a center of a large FOV to a center of a sub-FOV. The probing beam may be aligned at the center of the sub-FOV before scanning across the sub-FOV.

In step 540, after aligning the probing beam, the controller may adjust an excitation signal to a primary beam deflector or apply an excitation signal, to compensate for an off-axis aberration of the probing beam while scanning across the sub-FOV. For example, the controller may adjust the excitation signal to one or more beam deflectors 340a-e to compensate for an astigmatism aberration or field curvature aberration, or both, while performing a quick scan across the sub-FOV.

The electrical excitation signal may comprise a voltage signal, for example. In some embodiments, the excitation signal applied to a deflector to compensate the astigmatism aberration may be a supplemental excitation signal such as a voltage signal, in addition to the primary excitation signal applied to the deflector. The supplemental excitation signal may be substantially smaller than the primary excitation signal applied to the deflector. In this context, substantially smaller refers to 10% or less of the primary excitation signal. For example, if the primary excitation signal is 100 V, the supplemental excitation signal may be 10 V or less.

The supplemental excitation signal may be a predetermined voltage signal. The predetermined supplemental excitation signal to compensate the field curvature aberration or astigmatism aberration within a sub-FOV may be a constant signal such that the excitation signal is uniform across the sub-FOV. In some embodiments, the predetermined supplemental excitation signal to compensate the field curvature aberration may vary within a sub-FOV such that the excitation signal at pixels within a sub-FOV may be non-uniform. Controller 50 may be configured to adjust the excitation signal applied to the deflector associated with compensating for the off-axis aberration. In some embodiments, controller 50 may be configured to adjust the excitation signal at every pixel by applying a predetermined supplemental excitation signal, which may be similar or dissimilar.

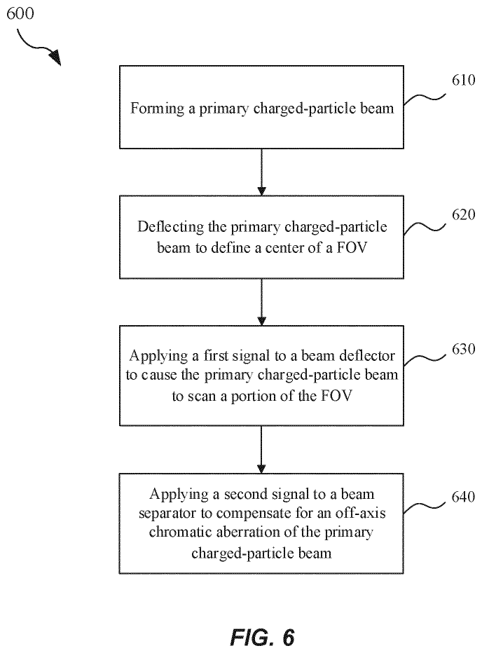

Reference is now made to FIG. 6, which illustrates a process flowchart representing an exemplary method 600 of imaging a large FOV of a sample, consistent with embodiments of the present disclosure. One or more steps of method 600 may be performed by controller 50 of EBI system 100, as shown in FIG. 2, for example. For example, controller 50 may instruct a module of a charged particle beam apparatus to activate a charged-particle source to generate charged particle beam (e.g., electron beam), apply electrical signals to beam deflectors, apply electrical signals to beam separators, and carry out other functions.

In step 610, a charged-particle source (e.g., electron source 302 of FIG. 3) may be activated to emit charged particles. The charged particles may pass through an aperture to form a charged-particle beam (e.g., primary charged-particle beam 304 of FIG. 3). The electron source may be activated by a controller (e.g., controller 50 of FIG. 3). For example, the electron source may be controlled to emit primary electrons to form an electron beam along a primary optical axis (e.g., primary optical axis 301 of FIG. 3). The electron source may be activated remotely, for example, by using a software, an application, or a set of instructions for a processor of a controller to power the electron source through a control circuitry. The primary electron beam may pass through a Coulomb aperture array (e.g., Coulomb aperture array 324 of FIG. 3) and a beam-limit aperture array (e.g., beam-limit aperture array 335 of FIG. 3) to adjust the beam size or beam current of the primary electron beam and form a probing beam (e.g., primary charged-particle beam 304-2 of FIG. 3).

In step 620, the probing beam may be deflected from the primary optical axis such that scanning the deflected probing beam on a surface of a sample (e.g., sample 350 of FIG. 3) forms a field-of-view (FOV). The controller may be configured to apply an excitation signal to one or more beam deflectors (e.g., primary charged-particle beam deflectors 340a-e of FIG. 3) in a beam manipulator assembly of the inspection apparatus (e.g., apparatus 300 of FIG. 3) to deflect the probing beam. The applied excitation signal may scan the deflected probing beam across a region of interest (ROI) to form the FOV of the image.

In step 630, the controller may apply an excitation signal to one or more beam deflectors to cause the probing beam to deflect and scan a sub-FOV. The controller may apply an excitation signal to one or more deflectors such as primary beam deflectors 340a, 340d, and 340e, to adjust the position of the probing beam from a center of a large FOV to a center of a sub-FOV. The probing beam may be aligned at the center of the sub-FOV before scanning across the sub-FOV.

In step 640, controller may apply an excitation signal to a beam separator (e.g., beam separator 348 of FIG. 3) to compensate for the energy dispersion caused by another beam separator (e.g., beam separator 346 of FIG. 3) and for the off-axis chromatic aberration of the primary probing beam. The beam separators may be electromagnetic beam separators such as Wien filters. Beam separator 346 may be configured to deflect the secondary electrons, generated upon interaction of the primary electrons of the probing beam with the sample, toward a secondary electron detector (e.g., detector 344 of FIG. 3). Beam separator 348 may comprise a compensation Wien filter configured to compensate for the energy dispersion and for the off-axis chromatic aberration.

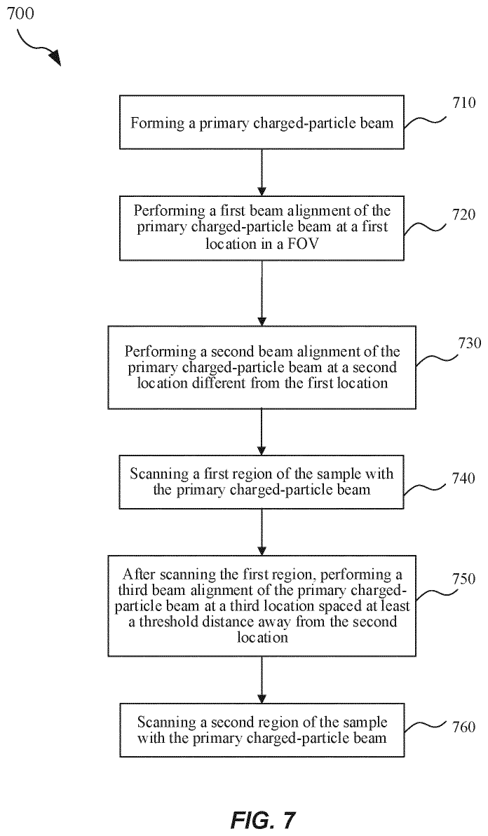

Reference is now made to FIG. 7, which illustrates a process flowchart representing an exemplary method 700 of imaging a large FOV of a sample, consistent with embodiments of the present disclosure. One or more steps of method 700 may be performed by controller 50 of EBI system 100, as shown in FIG. 2, for example. For example, controller 50 may instruct a module of a charged particle beam apparatus to activate a charged-particle source to generate charged particle beam (e.g., electron beam), apply electrical signals to beam deflectors, apply electrical signals to beam separators, and carry out other functions.

In step 710, a charged-particle source (e.g., electron source 302 of FIG. 3) may be activated to emit charged particles. The charged particles may pass through an aperture to form a charged-particle beam (e.g., primary charged-particle beam 304 of FIG. 3). The electron source may be activated by a controller (e.g., controller 50 of FIG. 3). For example, the electron source may be controlled to emit primary electrons to form an electron beam along a primary optical axis (e.g., primary optical axis 301 of FIG. 3). The electron source may be activated remotely, for example, by using a software, an application, or a set of instructions for a processor of a controller to power the electron source through a control circuitry. The primary electron beam may pass through a Coulomb aperture array (e.g., Coulomb aperture array 324 of FIG. 3) and a beam-limit aperture array (e.g., beam-limit aperture array 335 of FIG. 3) to adjust the beam size or beam current of the primary electron beam and form a probing beam (e.g., primary charged-particle beam 304-2 of FIG. 3).

In step 720, in a first beam alignment, the probing beam may be aligned at a first location of a FOV (e.g., center of FOV 470 of FIG. 4E). The first location may be a center of the FOV. The controller may be configured to apply an excitation signal to one or more beam deflectors (e.g., primary charged-particle beam deflectors 340a-e of FIG. 3) in a beam manipulator assembly of the metrology apparatus (e.g., apparatus 300 of FIG. 3). In some embodiments, the center of the FOV may be determined based on a spot or a region where the probing beam lands on the sample when there is no scanning being performed.

In step 730, in a second beam alignment, the probing beam may be repositioned or deflected to align with a center of a portion of the FOV, such as a first sub-FOV (e.g., sub-FOV 401 of FIG. 4E). The controller may apply an excitation signal to one or more beam deflectors to cause the probing beam to align with the center of the first sub-FOV. In some embodiments, the controller may apply an excitation signal to beam deflectors 340a, 340d, and 340e, to deflect the beam from the center of the FOV to a center of the sub-FOV. The center of the sub-FOV may be a different location than the center of the FOV.

In step 740, after aligning the probing beam to a center of the first sub-FOV, the controller may apply an excitation signal to one or more beam deflectors such as beam deflector 340b and 340c to cause the probing beam to scan across the first sub-FOV. In some embodiments, the excitation signal applied to one or more beam deflectors 340a, 340b, 340c, 340d, or 340e may be adjusted to compensate for the astigmatism aberration, or the field curvature aberration, or both, while the probing beam scans the first sub-FOV.

In step 750, after scanning the first sub-FOV, the controller may apply an excitation signal to one or more beam deflectors to deflect the probing beam to align with a center of a second sub-FOV (e.g. sub-FOV 402 of FIG. 4E). The second sub-FOV may be spaced at least a threshold distance away from the first sub-FOV to allow dissipation of charges and to minimize or mitigate the negative effects of charge build-up from the previous scan to a subsequent scan. The separation distance between successively scanned sub-FOVs may be maximized and uniform. The threshold distance of separation may depend on factors including, but not limited to, probing beam intensity, sample material, presence of defects, type of defects present, among other things, while considering the overall imaging quality and inspection throughput. In some embodiments, a large FOV may be divided into substantially equally sized sub-FOVs. In such cases, the threshold distance may be expressed in terms of unit sub-FOVs. For example, the threshold distance between two successively scanned sub-FOVs may be one sub-FOV, or two sub-FOVs, or three sub-FOVs, or any distance therebetween, or any appropriate distance.

In step 760, after aligning the probing beam to a center of the second sub-FOV, the controller may apply an excitation signal to one or more beam deflectors such as beam deflector 340b and 340c to cause the probing beam to scan across the second sub-FOV. In some embodiments, the excitation signal applied to one or more beam deflectors 340a-e may be adjusted to compensate for the astigmatism aberration, or the field curvature aberration, or both, while the probing beam scans the second sub-FOV.

A non-transitory computer readable medium may be provided that stores instructions for a processor of a controller (e.g., controller 50 of FIG. 1) to carry out image inspection, image acquisition, activating charged-particle source, adjusting electrical excitation of stigmators, adjusting landing energy of electrons, adjusting objective lens excitation, applying excitation signal to one or more beam deflectors, applying excitation signal to one or more beam separators, stage motion control, activating a beam deflector to deflect primary electron beam, applying electrical excitation signals including AC voltage, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:

1. A charged-particle beam apparatus comprising:
a charged-particle source configured to emit charged particles;
an aperture plate configured to form a primary charged-particle beam along a primary optical axis from the emitted charged particles;
a plurality of primary charged-particle beam deflectors configured to deflect the primary charged-particle beam to be incident on a surface of a sample to define a center of a field-of-view (FOV); and
a controller including circuitry configured to:
apply a first excitation signal to a primary charged-particle beam deflector of the plurality of primary charged-particle beam deflectors to cause the primary charged-particle beam to scan a portion of the FOV of the sample; and
apply a second excitation signal to cause the primary-charged particle beam deflector to compensate for an off-axis aberration of the primary charged-particle beam in the portion of the FOV of the sample.
   2. The apparatus of clause 1, wherein the second excitation signal comprises a predetermined voltage signal.
   3. The apparatus of clause 2, wherein the predetermined voltage signal is based on simulations from a trained machine learning model.
   4. The apparatus of any one of clauses 2 and 3, wherein the predetermined voltage signal is constant across the portion of the FOV of the sample.
   5. The apparatus of any one of clauses 2 and 3, wherein the predetermined voltage signal is varied based on a location of a probe spot in the portion of the FOV, the probe spot being formed by the primary charged-particle beam incident on the sample.
   6. The apparatus of clause 5, wherein the varying predetermined voltage signal enables dynamic compensation for the off-axis aberration of the primary charged-particle beam in the portion of the FOV of the sample.
   7. The apparatus of any one of clauses 1-6, wherein the plurality of primary charged-particle beam deflectors comprises electrostatic beam deflectors or magnetic deflectors.
   8. The apparatus of any one of clauses 1-7, wherein the portion of the FOV comprises a sub-FOV, and wherein the FOV comprises a plurality of sub-FOVs arranged in a two-dimensional array.
   9. The apparatus of clause 8, wherein each sub-FOV of the plurality of sub-FOVs is scanned by the primary charged-particle beam.
   10. The apparatus of clause 9, wherein before scanning each sub-FOV of the plurality of sub-FOVs, the primary charged-particle beam is aligned with a center of the each corresponding sub-FOV.
   11. The apparatus of any one of clauses 8-10, wherein the two-dimensional array comprises a symmetric array of sub-FOVs.
   12. The apparatus of any one of clauses 8-11, wherein the controller includes circuitry further configured to apply the second excitation signal to cause the primary-charged particle beam deflector to compensate for the off-axis aberration of the primary charged-particle beam while scanning a sub-FOV of the plurality of sub-FOVs.
   13. The apparatus of any one of clauses 8-11, wherein the controller includes circuitry further configured to apply the second excitation signal multiple times during a scan of the sub-FOV, to cause the primary-charged particle beam deflector to compensate for the off-axis aberration of the primary charged-particle beam while scanning the sub-FOV of the plurality of sub-FOVs.
   14. The apparatus of any one of clauses 1-13, wherein the off-axis aberration comprises a field curvature aberration or an astigmatism aberration of the primary charged-particle beam.
   15. The apparatus of clause 14, wherein the controller includes circuitry further configured to:
apply the second excitation signal to a first primary charged-particle beam deflector to cause the first primary-charged particle beam deflector to compensate for the field curvature aberration of the primary charged-particle beam; and
apply a third excitation signal to a second primary charged-particle beam deflector, different from the first primary charged-particle deflector, to cause the second primary-charged particle beam deflector to compensate for the astigmatism aberration of the primary charged-particle beam,
wherein the first and the second primary charged-particle beam deflectors are electrostatic beam deflectors.
   16. The apparatus of any one of clauses 1-15, further comprising a plurality of beam separators, wherein a first beam separator of the plurality of beam separators is configured to compensate for an energy dispersion of the primary charged-particle beam in the portion of the FOV, the energy dispersion caused by a second beam separator of the plurality of beam separators.
   17. The apparatus of clause 16, wherein the first beam separator is further configured to compensate for an off-axis chromatic aberration of the primary charged-particle beam in the portion of the FOV of the sample.
   18. The apparatus of any one of clauses 16 and 17, wherein the first beam separator is located upstream from the second beam separator, and wherein the first and the second beam separators comprise an electromagnetic beam separator.
   19. The apparatus of any one of clauses 17-18, wherein the first beam separator is further configured to receive an excitation signal from the controller, and wherein in response to receiving the excitation signal, the first beam separator compensates for the energy dispersion and the off-axis chromatic aberration of the primary charged-particle beam in the portion of the FOV of the sample.
   20. A method for imaging a sample using a charged-particle beam apparatus, the method comprising:
forming a primary charged-particle beam from charged particles emitted by a charged-particle source;
deflecting, by a primary charged-particle beam deflector, the primary charged-particle beam to be incident on a surface of a sample to define a center of a field-of-view (FOV);
applying a first excitation signal to the primary charged-particle beam deflector to cause the primary charged-particle beam to scan a portion of the FOV of the sample; and
applying a second excitation signal to cause the primary-charged particle beam deflector to compensate for an off-axis aberration of the primary charged-particle beam in the portion of the FOV.
   21. The method of clause 20, wherein applying the second excitation signal comprises applying a predetermined voltage signal to the primary charged-particle beam deflector.
   22. The method of clause 21, wherein the predetermined voltage signal is constant across the portion of the FOV of the sample.
   23. The method of clause 21, wherein the predetermined voltage signal is varied based on a location of a probe spot in the portion of the FOV, the probe spot being formed by the primary charged-particle beam incident on the sample.
   24. The method of clause 23, wherein varying the predetermined voltage signal allows dynamically compensating for the off-axis aberration of the primary charged-particle beam in the portion of the FOV of the sample.
   25. The method of any one of clauses 20-24, wherein the off-axis aberration comprises a field curvature aberration or an astigmatism aberration of the primary charged-particle beam.
   26. The method of clause 25, further comprising:
applying the second excitation signal to a first primary charged-particle beam deflector to cause the first primary-charged particle beam deflector to compensate for the field curvature aberration of the primary charged-particle beam; and
applying a third excitation signal to a second primary charged-particle beam deflector, different from the first primary charged-particle deflector, to cause the second primary-charged particle beam deflector to compensate for the astigmatism aberration of the primary charged-particle beam.
   27. The method of any one of clauses 20-26, wherein the portion of the FOV comprises a sub-FOV, and wherein the FOV comprises a plurality of sub-FOVs arranged in a two-dimensional array.
   28. The apparatus of clause 27, wherein each sub-FOV of the plurality of sub-FOVs is scanned by the primary charged-particle beam.
   29. The method of clause 28, wherein before scanning each sub-FOV of the plurality of sub-FOVs, the primary charged-particle beam is aligned with a center of the each corresponding sub-FOV.
   30. The method of any one of clauses 27-29, wherein the two-dimensional array comprises a symmetric array of sub-FOVs.
   31. The method of any one of clauses 20-30, further comprising applying an excitation signal to a first beam separator to compensate for an energy dispersion of the primary charged-particle beam in the portion of the FOV, the energy dispersion caused by a second beam separator.
   32. The method of clause 31, wherein applying the excitation signal to the first beam separator compensates for the energy dispersion and an off-axis chromatic aberration of the primary charged-particle beam in the portion of the FOV.
   33. The method of any one of clauses 31 and 32, wherein the first beam separator is located upstream from the second beam separator, and wherein the first and the second beam separators comprise an electromagnetic beam separator.
   34. A charged-particle beam apparatus comprising:
a charged-particle source configured to emit charged particles;
an aperture plate configured to form a primary charged-particle beam along a primary optical axis from the emitted charged particles; and
a plurality of primary charged-particle beam deflectors configured to deflect the primary charged-particle beam to be incident on a surface of a sample to define a center of a field-of-view (FOV);
a plurality of beam separators; and
a controller including circuitry configured to:
apply a first excitation signal to a primary charged-particle beam deflector of the plurality of primary charged-particle beam deflectors to cause the primary charged-particle beam to scan a portion of the FOV of the sample; and
apply a second excitation signal to a first beam separator of the plurality of beam separators to cause the first beam separator to compensate for an off-axis chromatic aberration of the primary charged-particle beam in the portion of the FOV.
   35. The apparatus of clause 34, further comprising a second beam separator located downstream from the first beam separator, and wherein the second excitation signal further compensates for an energy dispersion of the primary charged-particle beam in the portion of the FOV, the energy dispersion caused by the second beam separator.
   36. The apparatus of clause 35, wherein the first and the second beam separators comprise an electromagnetic beam separator or a Wien filter.
   37. The apparatus of any one of clauses 34-36, further comprising a charged-particle detector configured to detect secondary charged-particles generated from the sample upon interaction of the primary charged-particle beam and the sample.
   38. The apparatus of clause 37, wherein the first beam separator is located upstream from the charged-particle detector.
   39. The apparatus of any one of clauses 37 and 38, wherein the second beam separator is configured to deflect the secondary charged-particles to be detected by the charged-particle detector and allowing the primary charged-particle beam to pass through undeflected.
   40. The apparatus of any one of clauses 34-39, wherein the second excitation signal comprises a voltage and an electrical current signal.
   41. The apparatus of any one of clauses 34-40, wherein the second excitation signal comprises a predetermined excitation signal based on simulations from a trained machine learning model.
   42. The apparatus of any one of clauses 34-41, wherein the controller includes circuitry further configured to apply a third excitation signal to a primary charged-particle beam deflector of the plurality of primary charged-particle beam deflectors to cause the primary charged-particle beam deflector to compensate for an astigmatism aberration of the primary charged-particle beam in the portion of the FOV of the sample.
   43. The apparatus of clause 42, wherein the controller includes circuitry further configured to apply a fourth excitation signal to a primary charged-particle beam deflector of the plurality of primary charged-particle beam deflectors to cause the primary charged-particle beam deflector to compensate for a field curvature aberration of the primary charged-particle beam in the portion of the FOV of the sample.
   44. The apparatus of clause 43, wherein the third and the fourth excitation signals comprise a predetermined voltage signal.
   45. The apparatus of any one of clauses 34-44, wherein the primary charged-particle beam deflector of the plurality of primary charged-particle beam deflectors comprises an electrostatic beam deflector.
   46. A method for imaging a sample using a charged-particle beam apparatus, the method comprising:
forming a primary charged-particle beam from charged particles emitted by a charged-particle source;
deflecting, by a primary charged-particle beam deflector, the primary charged-particle beam to be incident on a surface of a sample to define a center of a field-of-view (FOV);
applying a first excitation signal to the primary charged-particle beam deflector to cause the primary charged-particle beam to scan a portion of the FOV of the sample; and
applying a second excitation signal to a first beam separator of a plurality of beam separators to cause the first beam separator to compensate for an off-axis chromatic aberration of the primary charged-particle beam in the portion of the FOV.
   47. The method of clause 46, wherein applying the second excitation signal further compensates for an energy dispersion of the primary charged-particle beam in the portion of the FOV, the energy dispersion caused by a second beam separator of the plurality of beam separators, located downstream from the first beam separator.
   48. The method of clause 47, wherein the first and the second beam separators comprise an electromagnetic beam separator or a Wien filter.
   49. The method of any one of clauses 46-48, further comprising detecting, using a charged-particle detector, secondary charged-particles generated from the portion of the FOV of the sample upon interaction of the primary charged-particle beam and the sample.
   50. The method of clause 49, wherein the first beam separator is located upstream from the charged-particle detector.
   51. The method of any one of clauses 48-50, further comprising deflecting, using the second beam separator, the secondary charged-particles to be detected by the charged-particle detector and allowing the primary charged-particle beam to pass through undeflected.
   52. The method of any one of clauses 46-51, wherein applying the second excitation signal comprises applying a voltage and an electrical current signal.
   53. The method of any one of clauses 46-52, wherein the second excitation signal comprises a predetermined excitation signal based on simulations from a trained machine learning model.
   54. The method of any one of clauses 46-53, further comprising applying a third excitation signal to a primary charged-particle beam deflector of the plurality of primary charged-particle beam deflectors to cause the primary charged-particle beam deflector to compensate for an astigmatism aberration of the primary charged-particle beam in the portion of the FOV of the sample.
   55. The method of clause 54, further comprising applying a fourth excitation signal to a primary charged-particle beam deflector of the plurality of primary charged-particle beam deflectors to cause the primary charged-particle beam deflector to compensate for a field curvature aberration of the primary charged-particle beam in the portion of the FOV of the sample.
   56. The method of clause 55, wherein the third and the fourth excitation signals comprise a predetermined voltage signal.
   57. The method of any one of clauses 46-56, wherein the primary charged-particle beam deflector of the plurality of primary charged-particle beam deflectors comprises an electrostatic beam deflector.
   58. A method for imaging a sample using a charged-particle beam apparatus, the method comprising:
forming a primary charged-particle beam from charged particles emitted by a charged-particle source of the charged-particle beam apparatus;
performing a first beam alignment of the primary charged-particle beam at a first location in a field-of-view (FOV) of the sample;
performing a second beam alignment of the primary charged-particle beam at a second location different from the first location;
scanning a first region of the sample with the primary charged-particle beam, the first region comprising a first portion of the FOV including the second location;
after scanning the first region, performing a third beam alignment of the primary charged-particle beam at a third location spaced at least a threshold distance away from the second location; and
scanning a second region of the sample with the primary charged-particle beam, the second region comprising a second portion of the FOV including the third location.
   59. The method of clause 58, wherein the first location comprises a center of the FOV of the sample.
   60. The method of any one of clauses 58 and 59, wherein the first region comprises a first sub-FOV and the second region comprises a second sub-FOV of the FOV of the sample.
   61. The method of any one of clauses 58-60, wherein the FOV comprises an array of sub-FOVs, and wherein the array comprises a two-dimensional symmetric array.
   62. The method of clause 61, wherein the threshold distance comprises a separation distance between the centers of adjacent sub-FOVs in the array.
   63. The method of any one of clauses 58-62, wherein the second location comprises a center of the first sub-FOV and the third location comprises a center of the second sub-FOV of the sample.
   64. A charged-particle beam apparatus comprising:
a charged-particle source configured to emit charged particles;
an aperture plate configured to form a primary charged-particle beam along a primary optical axis from the emitted charged particles;
a plurality of primary charged-particle beam deflectors configured to deflect the primary charged-particle beam to be incident on a surface of a sample; and
a controller including circuitry configured to cause a primary charged-particle beam deflector of the plurality of primary charged-particle beam deflectors to:
perform a first beam alignment of the primary charged-particle beam at a first location in a field-of-view (FOV) of the sample;
perform a second beam alignment of the primary charged-particle beam at a second location different from the first location;
scan a first region of the sample with the primary charged-particle beam, the first region comprising a first portion of the FOV including the second location;
perform a third beam alignment, after scanning the first region, of the primary charged-particle beam at a third location spaced at least a threshold distance away from the second location; and
scan a second region of the sample with the primary charged-particle beam, the second region comprising a second portion of the FOV including the third location.
   65. The apparatus of clause 64, wherein the first location comprises a center of the FOV of the sample.
   66. The apparatus of any one of clauses 64 and 65, wherein the first region comprises a first sub-FOV and the second region comprises a second sub-FOV of the FOV of the sample.
   67. The apparatus of any one of clauses 64-66, wherein the FOV comprises an array of sub-FOVs, and wherein the array comprises a two-dimensional symmetric array.
   68. The apparatus of clause 67, wherein the threshold distance comprises a separation distance between the centers of adjacent sub-FOVs in the array.
   69. The apparatus of any one of clauses 64-68, wherein the second location comprises a center of the first sub-FOV and the third location comprises a center of the second sub-FOV of the sample.
   70. The apparatus of any one of clauses 64-69, further comprising a charged-particle detector configured to detect secondary charged-particles generated from the sample upon interaction of the primary charged-particle beam and the sample.
   71. The apparatus of any one of clauses 64-70, further comprising a first beam separator configured to receive an excitation signal from the controller, the excitation signal upon being received, causes the first beam separator to compensate for an off-axis chromatic aberration of the primary charged-particle beam in a portion of the FOV being scanned.
   72. The apparatus of clause 71, further comprising a second beam separator located downstream from the first beam separator and configured to deflect the secondary charged-particles to be detected by the charged-particle detector.
   73. The apparatus of clause 72, wherein the first and the second beam separators comprise an electromagnetic beam separator or a Wien filter.
   74. The apparatus of any one of clauses 64-73, wherein the plurality of primary charged-particle beam deflectors comprises electrostatic beam deflectors or magnetic deflectors.
   75. The apparatus of any one of clauses 64-74, wherein the controller including circuitry is further configured to:
apply a first excitation signal to cause the primary charged-particle beam deflector to perform the first beam alignment;
apply a second excitation signal to cause the primary charged-particle beam deflector to perform the second beam alignment;
apply a third excitation signal to cause the primary charged-particle beam deflector to scan the first region of the sample with the primary charged-particle beam;
apply a fourth excitation signal to cause the primary charged-particle beam deflector to perform the third beam alignment after scanning the first region of the sample; and
apply a fifth excitation signal to cause the primary charged-particle beam deflector to scan the second region of the sample with the primary charged-particle beam.
   76. A non-transitory computer readable medium storing a set of instructions that is executable by one or more processors of a charged-particle beam apparatus to cause the charged-particle beam apparatus to perform a method of imaging a sample, the method comprising:
activating a charged-particle source to emit charged particles and forming a primary charged-particle beam from the emitted charged particles;
deflecting the primary charged-particle beam to be incident on a surface of the sample to define a center of a field-of-view (FOV);
applying a first excitation signal to a primary charged-particle beam deflector to cause the primary charged-particle beam to scan a portion of the FOV of the sample; and
applying a second excitation signal to cause the primary-charged particle beam deflector to compensate for an off-axis aberration of the primary charged-particle beam in the portion of the FOV.
   77. The non-transitory computer readable medium of clause 76, wherein applying the second excitation signal comprises applying a predetermined voltage signal to the primary charged-particle beam deflector.
   78. The non-transitory computer readable medium of clause 77, wherein the predetermined voltage signal is constant across the portion of the FOV of the sample.
   79. The non-transitory computer readable medium of clause 77, wherein the predetermined voltage signal is varied based on a location of a probe spot in the portion of the FOV, the probe spot being formed by the primary charged-particle beam incident on the sample.
   80. The non-transitory computer readable medium of clause 79, wherein varying the predetermined voltage signal allows dynamically compensating for the off-axis aberration of the primary charged-particle beam in the portion of the FOV of the sample.
   81. The non-transitory computer readable medium of any one of clauses 76-80, wherein the set of instructions that is executable by the one or more processors of the charged-particle beam apparatus causes the charged-particle beam apparatus to further perform:
applying the second excitation signal to a first primary charged-particle beam deflector to cause the first primary-charged particle beam deflector to compensate for a field curvature aberration of the primary charged-particle beam; and
applying a third excitation signal to a second primary charged-particle beam deflector, different from the first primary charged-particle deflector, to cause the second primary-charged particle beam deflector to compensate for an astigmatism aberration of the primary charged-particle beam.
   82. The non-transitory computer readable medium of any one of clauses 76-81, wherein the portion of the FOV comprises a sub-FOV, and wherein the FOV comprises a plurality of sub-FOVs arranged in a two-dimensional array.
   83. The non-transitory computer readable medium of clause 82, wherein each sub-FOV of the plurality of sub-FOVs is scanned by the primary charged-particle beam.
   84. The non-transitory computer readable medium of clause 83, wherein before scanning each sub-FOV of the plurality of sub-FOVs, the primary charged-particle beam is aligned with a center of the each corresponding sub-FOV.
   85. The non-transitory computer readable medium of any one of clauses 82-84, wherein the two-dimensional array comprises a symmetric array of sub-FOVs.
   86. The non-transitory computer readable medium of any one of clauses 76-85, wherein the set of instructions that is executable by the one or more processors of the charged-particle beam apparatus causes the charged-particle beam apparatus to further perform applying an excitation signal to a first beam separator to compensate for an energy dispersion of the primary charged-particle beam in the portion of the FOV, the energy dispersion caused by a second beam separator.
   87. The non-transitory computer readable medium of clause 86, wherein applying the excitation signal to the first beam separator compensates for the energy dispersion and an off-axis chromatic aberration of the primary charged-particle beam in the portion of the FOV.
   88. The non-transitory computer readable medium of any one of clauses 86 and 87, wherein the first beam separator is located upstream from the second beam separator, and wherein the first and the second beam separators comprise an electromagnetic beam separator.
   89. A non-transitory computer readable medium storing a set of instructions that is executable by one or more processors of a charged-particle beam apparatus to cause the charged-particle beam apparatus to perform a method of imaging a sample, the method comprising:
activating a charged-particle source to emit charged particles and forming a primary charged-particle beam from the emitted charged particles;
deflecting the primary charged-particle beam to be incident on a surface of a sample to define a center of a field-of-view (FOV);
applying a first excitation signal to a primary charged-particle beam deflector to cause the primary charged-particle beam to scan a portion of the FOV of the sample; and
applying a second excitation signal to a first beam separator of a plurality of beam separators to cause the first beam separator to compensate for an off-axis chromatic aberration of the primary charged-particle beam in the portion of the FOV.
   90. A non-transitory computer readable medium storing a set of instructions that is executable by one or more processors of a charged-particle beam apparatus to cause the charged-particle beam apparatus to perform a method of imaging a sample, the method comprising:
activating a charged-particle source to emit charged particles and forming a primary charged-particle beam from the emitted charged particles;
performing a first beam alignment of the primary charged-particle beam at a first location in a field-of-view (FOV) of the sample;
performing a second beam alignment of the primary charged-particle beam at a second location different from the first location;
scanning a first region of the sample with the primary charged-particle beam, the first region comprising a first portion of the FOV including the second location;
after scanning the first region, performing a third beam alignment of the primary charged-particle beam at a third location spaced at least a threshold distance away from the second location; and
scanning a second region of the sample with the primary charged-particle beam, the second region comprising a second portion of the FOV including the third location.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle beam apparatus comprising:
a charged-particle source configured to emit charged particles;
an aperture plate configured to form a primary charged-particle beam along a primary optical axis from the emitted charged particles;
a plurality of primary charged-particle beam deflectors configured to deflect the primary charged-particle beam to be incident on a surface of a sample to define a center of a field-of-view (FOV); and
a controller including circuitry configured to:
apply a first excitation signal to a primary charged-particle beam deflector of the plurality of primary charged-particle beam deflectors to cause the primary charged-particle beam to scan a portion of the FOV of the sample; and
apply a second excitation signal to cause the primary charged-particle beam deflector to compensate for an off-axis aberration of the primary charged-particle beam in the portion of the FOV of the sample.

2. The apparatus of claim 1, wherein the second excitation signal comprises a predetermined voltage signal.

3. The apparatus of claim 2, wherein the predetermined voltage signal is based on simulations from a trained machine learning model.

4. The apparatus of claim 2, wherein the predetermined voltage signal is constant across the portion of the FOV of the sample.

5. The apparatus of claim 2, wherein the predetermined voltage signal is varied based on a location of a probe spot in the portion of the FOV, the probe spot being formed by the primary charged-particle beam incident on the sample.

6. The apparatus of claim 5, wherein the varying predetermined voltage signal enables dynamic compensation for the off-axis aberration of the primary charged-particle beam in the portion of the FOV of the sample.

7. The apparatus of claim 1, wherein the plurality of primary charged-particle beam deflectors comprises electrostatic beam deflectors or magnetic deflectors.

8. The apparatus of claim 1, wherein the portion of the FOV comprises a sub-FOV, and wherein the FOV comprises a plurality of sub-FOVs arranged in a two-dimensional array.

9. The apparatus of claim 8, wherein each sub-FOV of the plurality of sub-FOVs is scanned by the primary charged-particle beam.

10. The apparatus of claim 9, wherein before scanning each sub-FOV of the plurality of sub-FOVs, the primary charged-particle beam is aligned with a center of the each corresponding sub-FOV.

11. The apparatus of claim 8, wherein the two-dimensional array comprises a symmetric array of sub-FOVs.

12. The apparatus of claim 8, wherein the controller includes circuitry further configured to apply the second excitation signal to cause the primary charged-particle beam deflector to compensate for the off-axis aberration of the primary charged-particle beam while scanning a sub-FOV of the plurality of sub-FOVs.

13. The apparatus of claim 8, wherein the controller includes circuitry further configured to apply the second excitation signal multiple times during a scan of the sub-FOV, to cause the primary charged-particle beam deflector to compensate for the off-axis aberration of the primary charged-particle beam while scanning the sub-FOV of the plurality of sub-FOVs.

14. The apparatus of claim 1, wherein the off-axis aberration comprises a field curvature aberration or an astigmatism aberration of the primary charged-particle beam.

15. A non-transitory computer readable medium storing a set of instructions that is executable by one or more processors of a charged-particle beam apparatus to cause the charged-particle beam apparatus to perform operations for imaging a sample, the operations comprising:
activating a charged-particle source to emit charged particles and forming a primary charged-particle beam from the emitted charged particles;
deflecting the primary charged-particle beam to be incident on a surface of the sample to define a center of a field-of-view (FOV);
applying a first excitation signal to a primary charged-particle beam deflector to cause the primary charged-particle beam to scan a portion of the FOV of the sample; and
applying a second excitation signal to cause the primary charged-particle beam deflector to compensate for an off-axis aberration of the primary charged-particle beam in the portion of the FOV.

16. The non-transitory computer readable medium of claim 15, wherein applying the second excitation signal comprises applying a predetermined voltage signal to the primary charged-particle beam deflector.

17. The non-transitory computer readable medium of claim 16, wherein the predetermined voltage signal is constant across the portion of the FOV of the sample.

18. The non-transitory computer readable medium of claim 16, wherein the predetermined voltage signal is varied based on a location of a probe spot in the portion of the FOV, the probe spot being formed by the primary charged-particle beam incident on the sample.

19. The non-transitory computer readable medium of claim 18, wherein varying the predetermined voltage signal allows dynamically compensating for the off-axis aberration of the primary charged-particle beam in the portion of the FOV of the sample.

20. The non-transitory computer readable medium of claim 15, wherein operations further comprise:
applying the second excitation signal to a first primary charged-particle beam deflector to cause the first primary charged-particle beam deflector to compensate for a field curvature aberration of the primary charged-particle beam; and
applying a third excitation signal to a second primary charged-particle beam deflector, different from the first primary charged-particle deflector, to cause the second primary charged-particle beam deflector to compensate for an astigmatism aberration of the primary charged-particle beam.
